(19) United States
(12) Patent Application Publication
(10) Pub. No.: US 2008/0179613 A1
(43) Pub. Date: Jul. 31, 2008

(54) Silicon Deflector on a Silicon Submount For Light Emitting Diodes

(75) Inventors: Matthias Wendt, Wurselen (DE); Gilles Ferru, Cairon (FR)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/915,629

(22) PCT Filed: May 31, 2006
(86) PCT No.: PCT/IB2006/051730

§ 371 Date: Nov. 27, 2007

(30) Foreign Application Priority Data
Jun. 2, 2005 (EP) 05104825.4

(51) Int. Cl. H01L 33/00; C23F 1/00; G02B 7/182

(52) U.S. Cl. 257/98; 216/2; 359/871; 257/E33.067

(57) ABSTRACT

The present invention deals with a process for the manufacturing of reflecting optical barriers comprising silicon and useful in combination with light emitting devices, wherein the process comprises anisotropic wet etching of the silicon material in such a manner that the rate of etching along the crystallographic (111) plane of the silicon material is slower than the rate of etching along the (110) and (100) planes. The present invention further comprises a reflecting optical barrier useful in combination with light emitting devices and a system containing at least one light emitting device comprising a reflecting optical barrier.

### FIELD OF THE INVENTION

The present invention is directed to a process for the manufacturing of reflecting optical barriers. In particular, the present invention is directed to a process for the manufacturing of reflecting optical barriers comprising silicon useful in the production of light emitting devices.

### BACKGROUND OF THE INVENTION

The large-volume application of high brightness light emitting diodes (LEDs) is well established for signalling and signage. They are expected to replace conventional lamps in lighting applications within a few years.

One of the interesting features of LEDs is the colour purity of the LED devices. This can be used in lamps with programmable beam colour. For multicolour LED lamps a number of LEDs with different colours need to be mounted in low distance of each other to make small light mixing optics possible.

A known principle to achieve a compact multi-chip module is to use naked LED chips mounted on a common substrate.

Due to the light emitting characteristics of the LEDs however, some of the light that is emitted towards the mounting surface or to the side gets absorbed in the neighbouring LEDs. This light is lost and cannot be directed to the front.

US 2004/0218390 A1 discloses a compact and efficient optical illumination system featuring planar multi-layered LED light source arrays concentrating their polarised or unpolarised output within a limited angular range. The optical system manipulates light emitted by a planar array of electrically interconnected LED chips positioned within the input apertures of a corresponding array of shaped metallic reflecting bins using at least one of elevated prismatic films, polarisation converting films, micro-lens arrays and external hemispherical or ellipsoidal reflecting elements. Practical applications of the LED array illuminating systems include compact LCD or DMD video image projectors as well as general lighting, automotive and LCD backlighting.

However, there still exist significant drawbacks in the state of the art as described above. One key element of this optical illumination system, the shaped metallic reflecting bins, is difficult to fabricate. One alternative is to employ forming tools and to emboss the desired pattern into a soft material. A second alternative is described in which a silicon substrate is subjected to reactive ion etching in order to obtain the desired form of the reflecting bin. In either case, the as-formed bin array sidewalls may need to be coated with a metallic film in order to obtain the desired reflecting properties.

Especially in the case of a silicon substrate, the process of reactive ion etching, being a plasma etching process and thus a dry process, is uneconomical due to the limited capacity of plasma etchers, it has a high energy requirement and it is difficult to control with respect to the formation of fine structures upon the substrate.

Therefore, there exists the need for a simple, economical and easy to control process for the manufacturing of reflecting optical barriers which can be used in combination with light emitting devices.

### SUMMARY OF THE INVENTION

This object is achieved according to the present invention in such a way that the process comprises anisotropic wet etching of the silicon material in such a manner that the rate of etching along the crystallographic (111) plane of the silicon material is slower than the rate of etching along the (110) and (100) planes.

This is especially advantageous due to the fact that the process of wet etching is scalable to a large extent and does not rely on power-consuming plasma ovens to operate.

As used in the present invention, the term “etching along a plane” means that the overall direction of removal of material is perpendicular to the plane of interest. Preferably, the order of the rate of etching of the silicon material is such that the etching along the (111) plane is slower that along the (100) plane which in turn is slower than along the (110) plane.

It has surprisingly been found that the process according to the present invention leads to surfaces of a high reflecting quality. Without being bound to a certain theory, it is noted that the (110) plane is the fastest etching primary surface. The ideal (110) surface has a more corrugated atomic structure than the (100) and (111) primary surfaces. The (111) plane is an extremely slow etching plane that is tightly packed, has a single dangling bond per atom and is overall atomically flat.

In one embodiment according to the present invention, the wet etching formulation comprises etchants selected from the group comprising hydroxide etchants, EDP (ethylene diamine/pyrocatechole/water) and/or hydrazine, preferably KOH.

Formulations for anisotropic potassium hydroxide (KOH) wet etching solutions can include, but are not limited to: 20% KOH:80% H₂O, 30% KOH:70% H₂O, 40% KOH:60% H₂O, 4 parts of 20% KOH:80% H₂O and 1 part isopropanol, 44% KOH:56% H₂O, 23.4% KOH:63.3% H₂O:13.3% isopropanol.

The operation temperature of anisotropic wet KOH etching according to the present invention can range from ≧20° C. to ≦120° C.

Table 1 lists the rate of silicon etching [μm/min] with an aqueous solution of KOH of given strength at a temperature of 70° C. with respect to the crystallographic plane within the silicon. The values in parentheses are normalised values relative to (110).

TABLE 1

| Crystallo- | Rates of silicon etching at different | | |
|---|---|---|---|
| graphic | KOH concentrations; 70° C.; [μm/min] | | |
| orientation | 30% | 40% | 50% |
| (110) | 1.455 (1.000) | 1.294 (1.000) | 0.870 (1.000) |
| (100) | 0.797 (0.548) | 0.599 (0.463) | 0.539 (0.619) |
| (111) | 0.005 (0.004) | 0.009 (0.007) | 0.009 (0.010) |

Formulations for anisotropic tetramethyl ammonium hydroxide (TMAH) wet etching solutions can include, but are not limited to: 5% TMAH:95% H₂O, 10% TMAH:90% H₂O, 2% TMAH:98% H₂O, 22% TMAH:88% H₂O, 22% TMAH:88% H₂O and 0.5% surfactant, 22% TMAH:88% H₂O and 1.0% surfactant.

The operation temperature of anisotropic wet TMAH etching according to the present invention can range from ≧20° C. to ≦90° C.

Table 2 lists the rate of silicon etching [μm/min] with an aqueous solution of 5% TMAH:95% H₂O at varying temperatures with respect to the crystallographic plane within the silicon. The values in parentheses are normalised values relative to (110).

TABLE 2

| Crys- | | | | | | | |
|---|---|---|---|---|---|---|---|
| tallo- | | | | | | | |
| graphic | Rates of silicon etching at different temperatures | | | | | | |
| orien- | 5% TMAH:95% H₂O; [μm/min] | | | | | | |
| tation | 60° C. | | 70° C. | 80° C. | | 90° C. | |
| (110) | 0.64 | (1.000) | 0.74 (1.000) | 1.4 | (1.000) | 1.8 | (1.000) |
| (100) | 0.33 | (0.515) | 0.48 (0.648) | 0.87 | (0.621) | 1.4 | (0.777) |

| | | | | | | |
|---|---|---|---|---|---|---|
| (111) | 0.026 | (0.040) | — | — | 0.034 | (0.018) |

Formulations for anisotropic ethylene diamine/pyrocatechole/water (EDP) wet etching solutions can include, but are not limited to (‘en’ denotes ethylene diamine, H₂N(CH₂)₂NH₂; ‘pc’ denotes pyrocatechole, C₆H₄(OH)₂):500 ml en:88 g pc:234 ml H₂O or 500 ml en:160 g pc:160 ml H₂O, 500 ml en:160 g pc:1 g pyrazine:160 ml H₂O, or 500 ml en:160 g pc:3 g pyrazine:160 ml H₂O, or 500 ml en:80 g pc:3.6 g pyrazine:66 ml H₂O, or 46.4 mol-% en:4 mol-% pc:49.4 mol-% H₂O, or 250 ml en:45 g pc:120 ml H₂O.

The operation temperature of anisotropic wet EDP etching according to the present invention can range from ≧50° C. to ≦120° C.

Table 3 lists the rate of silicon etching [μm/min] with a solution of 500 ml ethylene diamine:88 g pyrocatechole:234 ml H₂O at a temperature of 110° C. with respect to the crystallographic plane within the silicon. The values in parentheses are normalised values relative to (110).

TABLE 3

| Crystallographic | Rate of silicon etching (500 ml ethylene diamine:88 | |
|---|---|---|
| orientation | g pyrocatechole:234 ml H₂O; 110° C.); [μm/min] | |
| (110) | 0.28 | (1.000) |
| (100) | 0.47 | (1.678) |
| (111) | 0.028 | (0.100) |

In a further embodiment, the process for the manufacturing of reflecting optical barriers comprising silicon according to the present invention can be undertaken in the steps as depicted in FIGS. 1 to 6.

### DESCRIPTION OF THE DRAWINGS

FIG. 1 shows a silicon substrate (1), upon which a layer of silicon dioxide (2) and/or silicon nitride (3) is deposited.

FIG. 2 shows the silicon substrate (1) after patterning of the optical barrier by lithography, etching the silicon dioxide (2) and/or silicon nitride (3) layer.

FIG. 3 shows the silicon substrate (1) after performing anisotropic wet etching on the silicon substrate. Cavities (4) with a bottom surface (5) are formed.

FIG. 4 shows the silicon substrate (1) after further removal of the silicon dioxide and/or silicon nitride layer.

FIG. 5 shows the silicon substrate (1) that has been mounted on a foil (6).

FIG. 6 shows the silicon substrate (1) after grinding of the backside. The cavity (4) now does not comprise a bottom surface any more.

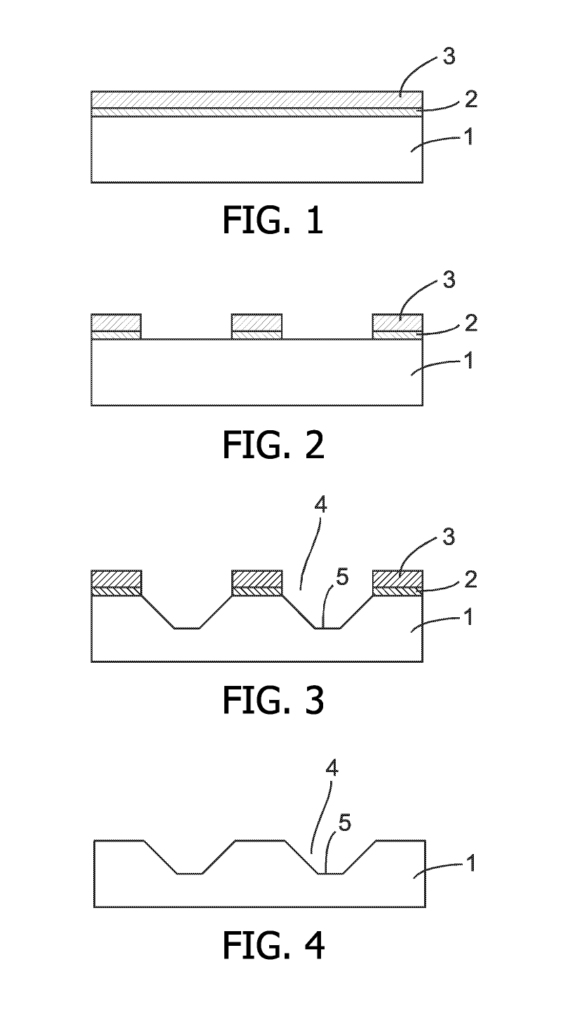

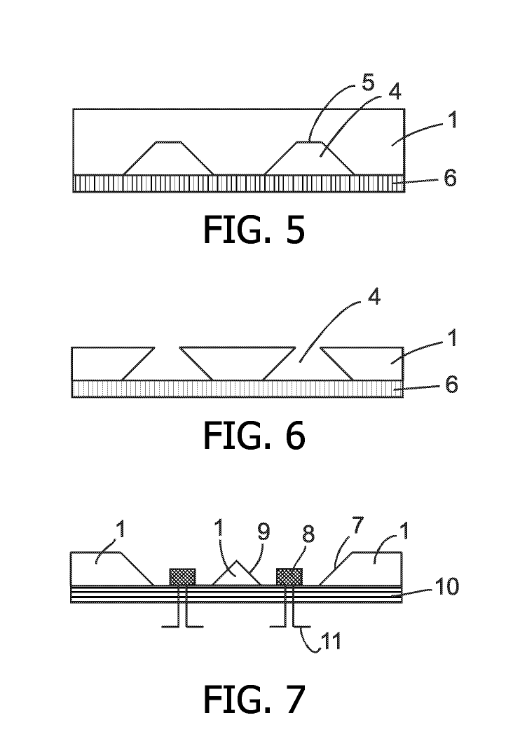

### DESCRIPTION OF THE PREFERRED EMBODIMENTS

In one embodiment of the present invention, the silicon material is wet etched to such an extent that a through-going opening is etched into the material. This has the advantage that the grinding step (FIG. 6) can be shortened or omitted. Alternatively, in another embodiment of the present invention, the silicon material is wet etched to such an extent that a cavity with a bottom is formed in the material. This has the advantage that the silicon material does not need to be immersed into the wet etching solution for a long time. Depending on the nature of the etchant, finer structures may be etched into the material in a shorter period of time. The back side of the silicon substrate is then subjected to grinding (as shown in FIG. 6).

In a preferred embodiment of the present invention, the process for the manufacturing of reflecting optical barriers comprising silicon according to the present invention comprises the following steps: grinding the silicon wafer to a given thickness which is equal to the desired height of the reflecting optical barrier; depositing one or a plurality of layers of silicon nitride onto the front side and the back side of said wafer; patterning the optical barrier by lithography; etching the silicon nitride layer on the side of the wafer where the optical barrier has been patterned by lithography; anisotropic wet etching of the silicon substrate; etching the silicon nitride remaining on the wafer; mounting the silicon wafer on a foil; sawing the wafer.

In a further preferred embodiment of the present invention, the optical barrier is coated with a reflecting surface, preferably silver and/or aluminium. The coating can be achieved by methods known in the art, such as sputtering, vapour deposition, chemical vapour deposition or metal-organic chemical vapour deposition. The additional coating with a reflecting surface can have beneficial effects upon the total light efficiency of the reflecting optical barrier.

In a further preferred embodiment of the present invention, the optical barrier is additionally equipped with guiding aides for mounting the optical barrier on a second surface. The second surface can be, but is not limited to, a submount comprising light emitting devices. A guiding aid according to the invention can be a protrusion or alternatively a cavity within the reflecting optical barrier. The guiding aides facilitate the mounting of two surfaces so that a production-type assembly can run more efficiently.

The scope of the present invention also comprises a reflecting optical barrier obtained by a process according to the present invention which is useful in combination with light emitting devices. Light emitting devices can be selected from the group comprising light emitting diodes (LEDs), organic light emitting diodes (OLEDs) and/or solid state lasers.

It is noted that the reflecting optical barrier obtained by a process according to the present invention is a separate entity and thus can be mounted upon a submount of light emitting devices. For example, it can be mounted upon a submount of light emitting diodes, organic light emitting diodes or semiconductor lasers. The reflecting optical barrier can be connected to the submount by adhesion forces, by means of an adhesive agent or by soldering. Due to the nature of the silicon material of the reflecting optical barrier, the barrier can be flexible. This has the advantage that small deviations from ideal planarity of the submount can be compensated.

As can be seen in FIG. 7, the reflecting optical barrier according to the present invention (1) is mounted upon a submount of light emitting devices (10). The light emitting devices (8) are electrically contacted from the side opposing the reflecting optical barrier. This has the advantage that no wiring components obstruct the reflection of light.

In a further embodiment according to the present invention, the cavity in the reflecting optical barrier comprising a light emitting device is sealed with a substance having a high refractive index. Such substances can be, but are not limited to, epoxy resins. This sealing leads to an improvement in the total light emission of the optical illuminating system which can be as high as 10%.

A reflecting optical barrier obtained by a process according to the present invention (as depicted in FIG. 7) can have a sidewall (7) height of ≧100 μm to ≦500 μm, and/or a light emitting device (8) height of ≧80 μm to ≦100 μm, and/or a central reflecting wall (9) height of ≧80 μm to ≦300 μm.

In a preferred embodiment, the reflecting optical barrier obtained by a process according to the present invention (as depicted in FIG. 7) has a sidewall (7) height of approximately 500 m, a light emitting device (8) height of approximately 100 m and a central reflecting wall (9) height of approximately 200 μm.

The reflecting optical barrier as obtained by the present invention can comprise one cavity into which a light emitting device can protrude. Alternatively, one reflecting optical barrier unit can comprise a plurality of cavities. For example, one reflecting optical barrier unit can comprise four cavities. This unit with four cavities can be useful for manufacturing light emitting devices according to the RGBA colour model. The RGBA colour model (red, green, blue and amber) is especially suited for lighting applications that demand white light. This unit with four cavities could incorporate a red, a blue, a green and an amber light emitting device.

The cavities in the reflecting optical barrier can be arranged regularly in a grid-like fashion. In another embodiment of the present invention, the cavities are arranged irregularly. As the cavities define the location of the light emitting devices, this can achieve an illuminating effect that is more pleasing to the eye.

One requirement for optical illumination systems comprising reflecting optical barriers and light emitting devices is that the position of the light emitting devices with respect to the reflecting optical barriers needs to be controlled precisely. According to the present invention, this requirement is met by the fact that the light emitting devices protrude into the cavities of the reflecting optical barriers, thereby being in a fixed position.

A reflecting optical barrier according the present invention can further comprise passive components, preferably selected from the group comprising electrical components, fluid ducts, gas ducts and/or optical waveguides. This is advantageous in many ways. A further integration of electric components such as electric circuitry can reduce the overall size of a system comprising the reflecting optical barrier. Additionally, in combination with piezoelectric material in the reflecting optical barrier, the direction of the reflection of the emitted light can be influenced. Fluid and gas ducts can for example serve the purpose of cooling the reflecting optical barrier during operation. Finally, optical waveguides can be used to transfer optically encoded information along the reflecting optical barrier.

A reflecting optical barrier according to the present invention comprising light emitting devices can be used for illumination purposes. For example, a system comprising a reflecting optical barrier according to the present invention, a light emitting diode (LED) or organic light emitting diode (OLED) can being used in one or more of the following applications: shop lighting, home lighting, head lamps, accent lighting, spot lighting, theatre lighting, office lighting, illumination of workplaces, automotive front lighting, automotive auxiliary lighting, automotive interior lighting, consumer TV applications, fibre-optics applications, projection systems, signaling, and signage.

All these applications benefit from the fact that the light efficiency and electrical efficiency can be improved.

To provide a comprehensive disclosure without unduly lengthening the specification, the applicant hereby incorporates by reference each of the patents and patent applications referenced above.

The particular combinations of elements and features in the above detailed embodiments are exemplary only; the interchanging and substitution of these teachings with other teachings in this and the patents/applications incorporated by reference are also expressly contemplated. As those skilled in the art will recognize, variations, modifications, and other implementations of what is described herein can occur to those of ordinary skill in the art without departing from the spirit and the scope of the invention as claimed. Accordingly, the foregoing description is by way of example only and is not intended as limiting. The invention's scope is defined in the following claims and the equivalents thereto. Furthermore, reference signs used in the description and claims do not limit the scope of the invention as claimed.

1-10. (canceled)

11. Process for the manufacturing of reflecting optical barriers comprising silicon useful in combination with light emitting devices, wherein the process comprises anisotropic wet etching of the silicon material in such a manner that the rate of etching along the crystallographic (111) plane of the silicon material is slower than the rate of etching along the (110) and (100) planes and wherein the process comprises the following steps: grinding the silicon wafer to a given thickness which is equal to the desired height of the reflecting optical barrier; depositing one or a plurality of layers of silicon nitride onto the front side and the back side of said wafer; patterning the optical barrier by lithography; etching the silicon nitride layer on the side of the wafer where the optical barrier has been patterned by lithography; anisotropic wet etching of the silicon substrate; etching the silicon nitride remaining on the wafer; mounting the silicon wafer on a foil; sawing the wafer.

12. Process according to claim 11, wherein the optical barrier is coated with a reflecting surface, preferably silver and/or aluminium.

13. Process according to claim 11, wherein the optical barrier is additionally equipped with guiding aides for mounting the optical barrier on a second surface.

14. Reflecting optical barrier obtained by a process according to claim 11 which is useful in combination with light emitting devices.

15. Reflecting optical barrier obtained by a process according to claim 11, wherein it has a sidewall height of ≧100 μm to ≦500 μm, preferably 500 μm, and/or a light emitting device height of ≧80 μm to ≦100 μm, preferably 100 μm and/or a central reflecting wall height of ≧80 μm to ≦300 μm, preferably 200 μm.

16. Reflecting optical barrier according to claim 14, further comprising passive components, preferably selected from the group comprising electrical components, fluid ducts, gas ducts and/or optical waveguides.

17. Use of a reflecting optical barrier according to claim 14 comprising light emitting devices for illumination purposes.

18. A system comprising a reflecting optical barrier according to claim 14, a light emitting diode (LED) or organic light emitting diode (OLED) being used in one or more of the following applications: shop lighting, home lighting, head lamps, accent lighting, spot lighting, theatre lighting, office lighting, illumination of workplaces, automotive front lighting, automotive auxiliary lighting, automotive interior lighting, consumer TV applications, fibre-optics applications, projection systems, signaling, and signage.
